(19) United States
(12) Patent Application Publication
(10) Pub. No.: US 2016/0238669 A1
(43) Pub. Date: Aug. 18, 2016

(54) Power System State Estimation Device and Power System State Estimation Method for Same

(71) Applicant: HITACHI, LTD., Chiyoda-ku, Tokyo (JP)

(72) Inventors: Masatoshi KUMAGAI, Tokyo (JP); Shota OMI, Tokyo (JP); Kenichiro YAMANE, Tokyo (JP); Masahiro WATANABE, Tokyo (JP)

(21) Appl. No.: 15/027,614

(22) PCT Filed: Oct. 7, 2013
(86) PCT No.: PCT/JP2013/077199

§ 371 Date: Apr. 6, 2016

(51) Int. Cl. G01R 31/40; G01R 27/16

(52) U.S. Cl. CPC G01R 31/40; G01R 27/16

(57) ABSTRACT

A power system state estimation device for estimating a state amount of a power system having: a calculation unit which executes calculations on the power system; a system division unit which is inputted with system information and a measured value of the state amount of the power system to divide the power system into an observable subsystem and an unobservable subsystem;

a state estimation unit that is inputted with the system information and the measured value of the state amount to calculate an estimated value of the state amount in the observable subsystem divided by the system division unit; and a state range estimation unit that is inputted with the system information, the measured value of the state amount and a constraint value of the state amount of the power system to calculate an estimated range of the state amount in the unobservable subsystem divided by the system division unit.

### TECHNICAL FIELD

The present invention relates to a power system state estimation device and a power system state estimation method for the same to estimate a state of a power system.

### BACKGROUND ART

In a power system, or a power distribution system, it is important to perceive a state of the entire power system for properly controlling and managing the system even when a power flow fluctuates due to variation in loads or the like. As a technique for perceiving the state in the entire power system, Patent Document 1, for example, discloses a technique, based on measured values such as a voltage and a current by sensors installed in the power distribution system and a power flow calculation with system configuration data, of calculating a correction amount for the system state with an estimated values of measurement errors and the power flow calculation to accurately estimate real values of the system state.

### PRIOR ART DOCUMENT

### Patent Document

Patent document 1: Japanese Patent Application Publication No. 2008-154418

### SUMMARY OF THE INVENTION

### Problem to be Solved by the Invention

The technique disclosed in Patent Document 1 described above allows, based on the measured values such as the voltage and the current by the sensors installed in the power distribution system and the power flow calculation with the system configuration data, for calculating the correction amount for the system state with the estimated values of the measurement errors and the power flow calculation to accurately estimate the real values of the system state.

However, the above technique is assumed to have an observable system in which sensors are redundant in number relative to amounts of system state, which causes a problem such that the technique cannot be applied to estimation of a state amount in an unobservable system in which sensors are insufficient in number relative to the amounts of system state.

Accordingly, the present invention is to solve such a problem, and an object of the present invention is to estimate and perceive a state amount with an estimated range of the state amount even in an unobservable subsystem where only a part of the state amount is measured, in addition to perceiving a state amount in an observable subsystem in an power system.

### Means for Solving the Problem

To solve the problem described above, the present invention is configured as follows.

In short, the present invention is to provide a power system state estimation device for estimating a state amount of a power system having: a calculation unit which executes calculations on the power system; a system division unit which is inputted with system information and a measured value of the state amount of the power system to divide the power system into an observable subsystem and an unobservable subsystem with reference to a calculation result of he calculation unit; a state estimation unit which is inputted with the system information and the measured value of the state amount to calculate an estimated value of the state amount in the observable subsystem divided by the system division unit with reference to the calculation result of the calculation unit; and a state range estimation unit which is inputted with the system information, the measured value of the state amount and a constraint value of the state amount of the power system to calculate an estimated range of the state amount in the unobservable subsystem divided by the system division unit.

Other devices/units will be described in a detailed description of an embodiment.

### Advantageous Effects Of The Invention

According to the present invention, a state amount can be estimated and perceived with an estimated range of a state amount even in an unobservable subsystem where only a part of the state amount is measured, in addition to perceiving a state amount in an observable subsystem in an power system.

### BRIEF DESCRIPTION OF THE DRAWINGS

FIG. 1 is a diagram showing a configuration example of a power system state estimation device according to an embodiment of the present invention and its relation with a power system, information acquisition devices for perceiving a state of the power system, and peripheral devices of the subject device.

FIG. 2 is a diagram showing a configuration example of respective elements in the power system according to the embodiment of the present invention and an example of node numbers assigned to respective elements;

FIG. 3 is a diagram showing notations such as parameters of an SVR and an SVC in a power system control system according to the embodiment of the present invention;

FIG. 4 is a schematic diagram showing a calculation method for the maximum value of each element in a redundant solution from the maximum value of a solution norm in the redundant solution;

FIG. 5 is a schematic diagram showing a calculation method for a value range of the redundant solution;

FIG. 6 is a flowchart showing an algorithm of a third method with which the value range of the redundant solution according to the embodiment of the present invention is limited;

FIGS. 7A and 7B show an example of a screen display on a display device, in which FIG. 7A shows representative values of the state amount and a range of the state amount in each node, and FIG. 7B shows a system diagram of the power system;

FIG. 8 is a table showing an example of a system log which a recording device outputs; and

FIG. 9 is an exemplary flowchart showing processing of the power system state estimation device according to the embodiment of the present invention.

### EMBODIMENTS FOR CARRYING OUT THE INVENTION

Hereinafter, a description will be given of an embodiment of the present invention with reference to the drawings.

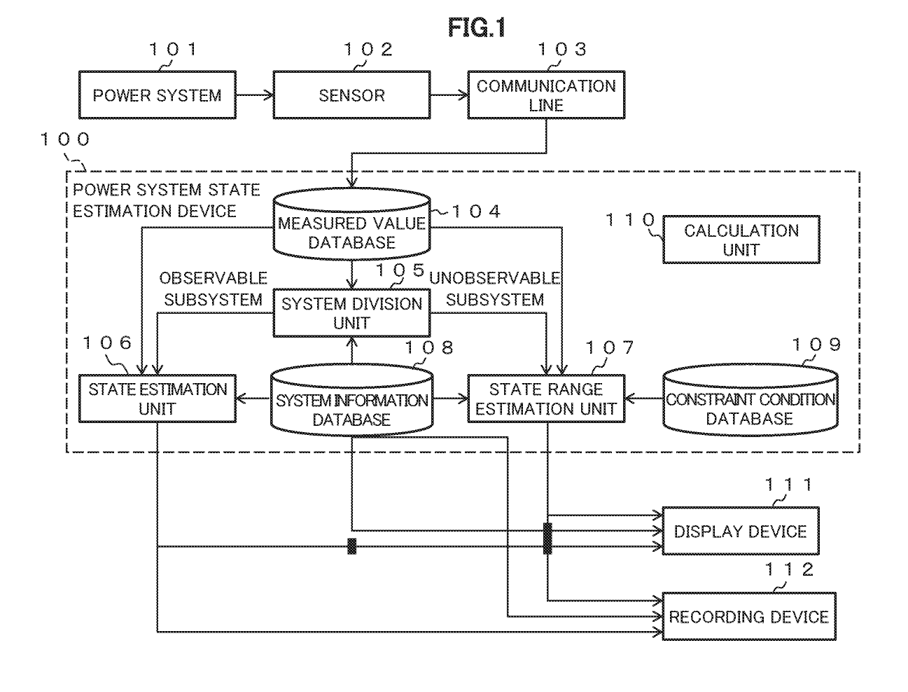

FIG. 1 is a diagram showing a configuration example of a power system state estimation device 100 according to an embodiment of the present invention, and its relation with a power system 101 and information acquisition devices (sensor 102, communication line 103) which perceive a state of the power system, and peripheral devices (display device 111, recording device 112) of the power system state estimation device 100.

In FIG. 1, a state amount such as a voltage and a current of the power system 101 is measured by the sensor 102 so as to be outputted via the communication line 103 to the power system state estimation device 100 as a measured value of the state amount. The power system state estimation device 100 estimates the state amount of the power system 101 to output the estimated result to the display device 111 and the recording device 112. It is noted that respective signals from a state estimation unit. 106, a system information database 108 and a state range estimation unit 107 cross with one another at some points on the way to the display device 111 or the recording device 112. Those points are shown by black boxes, which indicate that respective signals described above cross with one another but are never connected.

Next, a configuration of the power system state estimation device 100, the display device 111 and the recording device 112 will be described in order.

In addition, the power system 101 will be described in detail by way of an example, in a description of a mathematical model of the power system used in the power system state estimation device 100.

It is noted that the sensor 102 and the communication line 103 are common ones, and detailed descriptions thereof are omitted.

### <<Power System State Estimation Device>>

The power system state estimation apparatus 100 is configured to include a measured value database 104, a system division unit 105, a state estimation unit 106, a state range estimation unit 107, a system information database 108, a constraint condition database 109, and a calculation unit 110.

The measured value database 104 records the measured value of the state amount in the power system obtained via the communication line 103.

The system division unit 105 is inputted with system information and the measured value of the state amount of the power system 101 to divide the power system into an observable subsystem and an unobservable subsystem with reference to a calculation result of the calculation unit 110.

The state estimation unit 106 is inputted with the system information and the measured value of the state amount of the power system 101 to calculate an estimated value of the state amount in the observable subsystem divided by the system division unit 105.

The state range estimation unit 107 is inputted with the system information and the measured value of the state amount of the power system 101 and a constraint value of the state amount of the power system 101 to calculate an estimated range of the state amount in the unobservable subsystem divided by the system division unit 105, with reference to the calculation result of the calculation unit 110.

The system information database 108 records the system information about the configuration of the power system 101, such as line impedance and system topology.

The constraint condition database 109 records the constraint value of the state amount cDf the power system 101.

The calculation unit 110 executes calculations on the power system. Further, the calculation unit 110 calculates about the system division unit 105, the state estimation unit 106 and the state range estimation unit 107, to assist a function and an operation of each device (105, 106, 107)

Still further, the power system state estimation unit 100, having the configuration described above, is inputted with the measured value of the state amount, estimates the state amount of the power system and outputs the estimated value of the state amount and the estimated range of the state amount.

It is noted that the power system state estimation device 100 and functions, operations, calculation methods and the like of respective devices constituting the device 100 will be described later in more detail in the description of the mathematical model to be described later.

### <<Display Device and Recording Device>>

In FIG. 1, the power system state estimation device 100 is connected with the display device 111 and the recording device 112 as peripheral devices.

The display device 111 outputs the estimated value of the state amount and the estimated range of the state amount as output of the power system state estimation device 100 on a screen in numerical values or in a graph. Also, in conjunction with a system diagram showing system information, the display device 111 displays the estimated value of the state amount and the estimated range of the state amount. It is noted that a function of the display device 111 will be described later in detail.

The recording device 112 records, in the same manner, the estimated value of the state amount and the estimated range of the state amount as the system log. Further, the recording device 112 outputs the record to a recording medium it is noted that a function of the recording device 112 will be described later in detail.

Still further, in FIG. 1, the display device 111 and the recording device 112 have been shown as devices connected outside the power system state estimation device 100, but they may be arranged as parts in the power system state estimation device 100.

### <<Mathematical Model of Power System>>

Next, the function of the power system state estimation device 100 (FIG. 1) will be described by presenting the power system in a mathematical model. It is noted that the system information database 108 (FIG. 1) records the system topology of the power system, using the mathematical model to be described below.

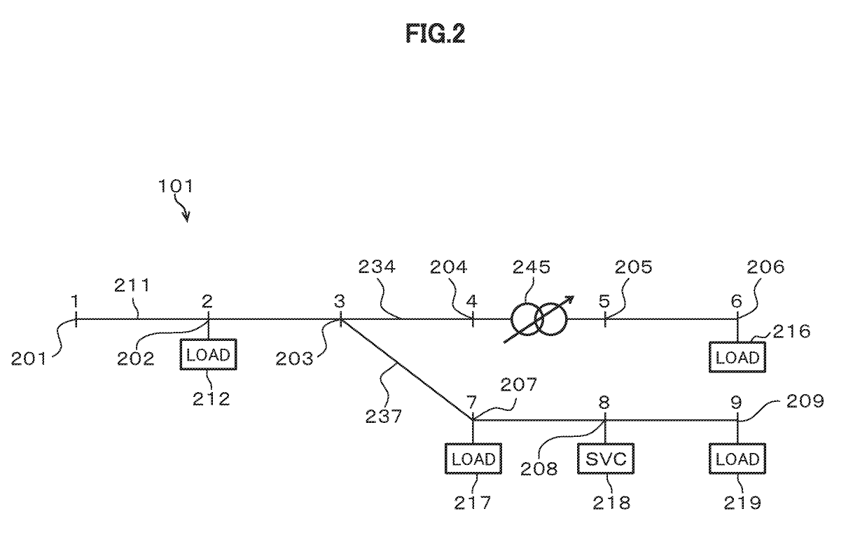

Referring to FIG. 2 showing an example of the power system, the system topology of the power system will be described. First, a node number presenting the system topology of the power system, an adjacency matrix and a hierarchical matrix will be described in order.

### <<Node Number>>

FIG. 2 is a diagram showing a configuration example of respective elements in the power system 101 according to the embodiment of the present invention and an example of node numbers assigned to respective elements.

FIG. 2 shows a state in which (AC) voltage is transmitted from a power transmission end 201 to a power distribution line 211 in the power system 101.

The power distribution line 211, first, includes a load end 202 connected with a load 212, and then, a branch end 203. The power distribution line 211 branches off at the branch end 203 to a first power distribution system 234 and a second power distribution system 237.

The first power distribution system 234 includes an SVR 245 having an SVR end 204 at an input side and an SVR end 205 at an output side, respectively. Then, the SVR end 205 is connected with a load end 206 connected with a load 216.

Further, the second power distribution system 237 branched off at the branch end 203, first, includes a load end 207 connected with a load 217, and then, an SVC end 208 connected with an SVC 218. Furthermore, the SVC end 208 is connected with a load end 209 connected with a load 219.

It is noted that the SVR stands for a Step Voltage Regulator and the SVC stands for a Static Var Compensator. In addition, the SVR and SVC are used to regulate the voltage of the power system, and then fail in the category of a voltage regulator.

In FIG. 2, the SVR and SVC are exemplified as voltage regulators in series with the power system and in parallel with the power system, respectively, but the voltage regulators on the power system are not limited thereto.

Further, if a distributed power source is connected to the power system, it is shown in the same manner as the load end 202. Still further, in FIG. 2, the sensor 102 (FIG. 1) is not shown.

At mathematical modeling of the above power system, node numbers are assigned to main points in the power system.

As shown in FIG. 2, node numbers 1 to 9 are exclusively assigned to the power transmission end 201, the load end 202, the branch end 203, the SVR end 204, the SVR end 205, the load end. 206, the load end 207, the SVC end 208 and the load end 209, respectively in order.

In addition, the connection relation between nodes is presented by the adjacency matrix and the hierarchy matrix to be described later. Firstly, the adjacency matrix will be explained, and secondly, the hierarchy matrix will be explained.

### <<Adjacency Matrix>>

A description will be given of the adjacency matrix. The adjacency matrix defines an adjacency relation of an upstream and downstream (the upstream is closer to the power transmission end and the downstream is further from the power transmission end) of the nodes as a mathematical presentation. In addition, depending on the upstream and downstream, an upstream adjacency matrix U and a downstream adjacency matrix D are defined, respectively. Next, they will be described in order.

### <<Upstream Adjacency Matrix U>>

An element uₚ of the upstream adjacency matrix U is defined to be an upstream adjacent node (node number) of a node p. According to the definition, the example in FIG. 2 is expressed with the upstream adjacent node of each node, starting from the the node 1, left to right, in order as in the following Equation 1. It is noted that 0 indicates no corresponding node.

In FIG. 2, P of the node p is defined as 0≦p≦8.

[Equation 1]

U=[0 1 2 3 4 5 3 7 8] Equation 1

### <<Downstream Adjacency Matrix D>>

Next, a description will be given of the downstream adjacency matrix D.

Each element dₙₚ of the downstream adjacency matrix D is defined to be a downstream adjacent node (node number) of the node p in a path to a node n. It is noted that 0 indicates no corresponding node.

Further, while the upstream adjacent node is unique, the downstream adjacent node may not be unique due to branching, and in FIG. 2, the path to the node 5 has a different downstream adjacent node of the node 3 from that to the node 8.

In addition, on lines 8 and 9 in the equation 2 to be described later, numbers 0,0,0 are present between the downstream adjacency matrix elements d_{8,3} and d_{6,7}, and between d_{9,3} and d_{9,7} corresponding to the node number 3 (presented as 7) and the node number 7 (presented as 8). The elements where numbers 0, 0, 0 are present originally correspond to the node numbers 4, 5 and 6. However, since the paths to the nodes 7 and 8 in FIG. 2 do not include nodes (4, 5, 6), the numbers 0, 0, 0 are presented.

Such a presentation is for the convenience of the mathematical processing of the present system, and comes from the definitions described above. According to these definitions, all the elements are written for the example shown in FIG. 2, to obtain the following determinant in Equation. 2.

$$\begin{matrix}[ Equation 2 ] & \\ D = [ \begin{matrix}0 & 0 & 0 & 0 & 0 & 0 & 0 & 0 & 0 \\ 2 & 0 & 0 & 0 & 0 & 0 & 0 & 0 & 0 \\ 2 & 3 & 0 & 0 & 0 & 0 & 0 & 0 & 0 \\ 2 & 3 & 4 & 0 & 0 & 0 & 0 & 0 & 0 \\ 2 & 3 & 4 & 5 & 0 & 0 & 0 & 0 & 0 \\ 2 & 3 & 4 & 5 & 6 & 0 & 0 & 0 & 0 \\ 2 & 3 & 7 & 0 & 0 & 0 & 0 & 0 & 0 \\ 2 & 3 & 7 & 0 & 0 & 0 & 8 & 0 & 0 \\ 2 & 3 & 7 & 0 & 0 & 0 & 8 & 9 & 0\end{matrix} ] & Equation 2\end{matrix}$$

### <<Hierarchy Matrix C_{D}>>

Next, a description will be given of a hierarchy matrix C_{D}.

The hierarchy matrix C_{D} is defined to be a mathematical presentation which presents a connection relation of the upstream and downstream regardless of whether they are adjacent or not. Respective elements C_{Dnp} take values described in the following. Equation 3A according to the connection relation. Further, the definition by the elements is applied to the example shown in FIG. 2, to obtain the hierarchical matrix C_{D} as a determinant shown in the following Equation 3B.

$$\begin{matrix}[ Equation 3 A ] & \\ {C}_{D np} = \{ \begin{matrix}1 \text{:} & n is a downstream node of p \\ 0 \text{:} & Other\end{matrix} & Equation 3 A \\ [ Equation 3 B ] & \\ {C}_{D} = [ \begin{matrix}0 & 0 & 0 & 0 & 0 & 0 & 0 & 0 & 0 \\ 1 & 0 & 0 & 0 & 0 & 0 & 0 & 0 & 0 \\ 1 & 1 & 0 & 0 & 0 & 0 & 0 & 0 & 0 \\ 1 & 1 & 1 & 0 & 0 & 0 & 0 & 0 & 0 \\ 1 & 1 & 1 & 1 & 0 & 0 & 0 & 0 & 0 \\ 1 & 1 & 1 & 1 & 1 & 0 & 0 & 0 & 0 \\ 1 & 1 & 1 & 0 & 0 & 0 & 0 & 0 & 0 \\ 1 & 1 & 1 & 0 & 0 & 0 & 1 & 0 & 0 \\ 1 & 1 & 1 & 0 & 0 & 0 & 1 & 1 & 0\end{matrix} ] & Equation 3 B\end{matrix}$$

The downstream adjacency matrix D and the hierarchical matrix C_{D} are redundant presentations of the upstream adjacency matrix U, and are frequently used presentations for describing the mathematical model. Further, as long as the topology of the power distribution system remains unchanged, the downstream adjacency matrix D and the hierarchical matrix C_{D} have unchanged constants, and therefore may be generated for implementation in 30 advance based on the upstream adjacency matrix U.

To clarify the presentations of the mathematical model below, the above-mentioned Uₚ, dₙₚ, C_{Dnp} will be presented as u (P) d(n, p), C_{D}(n, P) as appropriate.

### <<Parameter Presentation on SVR and SVC>>

Before a power equation at the node p is described, presentations of parameters and the like on the SVR (Step Voltage Regulator) and the SVC (Static Var Compensator) will be described.

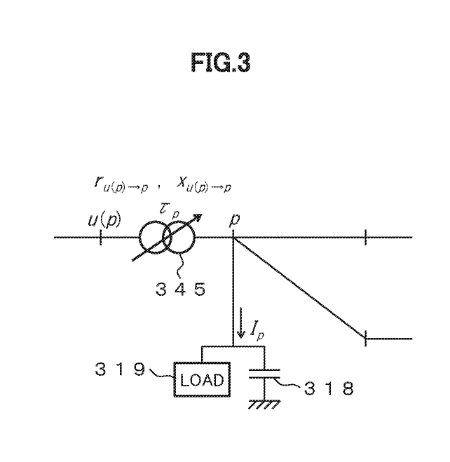

FIG. 3 is a diagram showing presentations of the parameters and the like on an SVR 345 and an SVC 318 in the power system control system according to the embodiment of the present invention.

In FIG. 3, the SVR 345 is arranged between the node p and the upstream adjacent node u (p). A tap ratio for voltage regulation by the SVR 345 is presented as τₚ.

In addition, assuming that there is no SVR 345, a resistance component of impedance of the branch between the node u (p) and the node p is presented as r_{u(P)}→_{P} and a reactance component as X_{u(p)→p}.

Further, assuming that the node p is connected with a load 319 and the SVC 318, a current flowing into or out of the load 319 or the SVC 318 at the node P is presented as Iₚ.

It is noted that the SVC 318 is presented by a general symbol of a capacitor, but the SVC 318 has a function capable of supplying a lagging current, in addition to a leading current of the capacitor.

### <<Power Equation for Branch>>

Next, a description will be given of power equations (Equations 4A and 4B) for a branch. These equations are established between adjacent nodes (u(p), p). It is noted that an element connecting adjacent nodes is referred to as a branch.

In the following Equation 4A, a voltage and a current of the node P are presented as Vₚ and Iₚ.

Further, a passing current which passes through the node P is presented as I′ₙ(p) for a node current In at any downstream node n.

Still further, as a presentation of circuit impedance which is set in the system information database 108 (FIG. 1), the branch from the adjacent node u(p) to the node p (corresponding to the power distribution line) is presented as u(p)→p as a subscript, as described above.

In other words, the resistance component and the reactance component of the impedance are presented as r_{u(p)→p}, x_{u(p)→p}, and the impedance is presented as (r_{u(p)→p}+jx_{u(p)→p}).

As mentioned above, the τₚ is the tap ratio of the SVR.

It is noted that, in the Equations 4A and 4B, Vₚ, Vᵤ₍ₚ₎, Iₚ, I′ₙ₍ₚ₎, Iₙ as AC (complex numbers) are presented with dots of a modified symbol over the characters, but the dots are omitted in the description for the convenience of presentation.

$$\begin{matrix}[ Equations 4 A and 4 B ] & \\ {τ}_{p} {\dot{V}}_{u ( p )} = {\dot{V}}_{p} + ( {r}_{u ( p ) \to p} + {jx}_{u ( p ) \to p} ) ( {i}_{p} + {\sum }_{n = 1}^{N} {C}_{D} ( n , p ) {i}_{n}^{′} ( p ) ) & Equation 4 A \\ {i}_{n}^{′} ( p ) = ( {τ}_{d ( n , p )} \times {τ}_{d ( n , d ( n , p ) )} \times … \times {τ}_{n} ) {i}_{n} & Equation 4 B\end{matrix}$$

It is noted that, in Equation 4A, a term including a coefficient τₚ is associated with the SVR (Step Voltage Regulator) and a pole transformer, and a term including I′ₙ₍ₚ₎ is associated with the SVC (Static Var Compensator) and a load.

Further, in Equation 4B, the subscript d(n, p) of the τ is, as described above, the element dₙₚ of the downstream adjacency matrix D, and furthermore, d(n, d(n, p)) indicates a relation between the n and the d(n, p) to follow downstream in order.

### <<Presentation by Determinant of Power Equation>>

As to the power equation, a linear equation on the voltage and the current of the branch u(p)→p described in Equations 4A, 4B is established for combinations of all the adjacent nodes. In short, the number of equations is (N-1) for the number of nodes N, and they are collectively presented as the following matrix equation.

$$\begin{matrix}[ Equation 5 ] & \\ A [ \begin{matrix}{\dot{V}}_{1} \\ ⋮ \\ {\dot{V}}_{N} \\ {i}_{1} \\ ⋮ \\ {i}_{N}\end{matrix} ] = [ {0}_{N - 1} ] & Equation 5\end{matrix}$$

Here, A is a coefficient matrix formed with the impedance r_{u(p)→p} and x_{u(p)→p}, the tap ration τₚ and the hierarchy matrix C_{D}(n, p) Since there are 2N variables (N voltages and N currents), the size of A is (N-1)×2N.

Further, in Equation 4A, since all the terms include either Vₚ or Iₚ, [0_{N-1}] on the right side in Equation 5 is a vector to make all the elements 0.

### <<Extended Matrix Equation>>

Since Equation 5 does not include the information of the measured value of the state amount recorded in the measured value database 104, terms which relate to matrices M_{V}, M_{I} describing presence or absence of the measured value of the state amount on the voltage and current are added to extend Equation 5 to the following Equation 6. It is noted that the matrices M_{V}, M_{I} will be described later.

$$\begin{matrix}[ Equation 6 ] & \\ [ \begin{matrix}A \\ … \\ {M}_{V} \\ {M}_{I}\end{matrix} ] [ \begin{matrix}{\dot{V}}_{1} \\ ⋮ \\ {\dot{V}}_{N} \\ {i}_{1} \\ ⋮ \\ {i}_{N}\end{matrix} ] = [ \begin{matrix} & {0}_{N - 1} \\ & … \\ \begin{matrix}{M}_{V} \\ {M}_{I}\end{matrix} & [ \begin{matrix}{\tilde{V}}_{1} \\ ⋮ \\ {\tilde{V}}_{N} \\ {\tilde{I}}_{1} \\ ⋮ \\ {\tilde{I}}_{N}\end{matrix} ]\end{matrix} ] & Equation 6\end{matrix}$$

In Equation 6, V₁ . . . V_{N}, I₁ . . . I_{N} on the right side are measured values of the state amount of the voltage and current at the node p (1≦p≦N). It is noted that, on the left side in Equation 6, (V₁ . . . V_{N}, I₁ . . . I_{N}) having dots of a modified symbol of a vector value of AC (complex number) over the characters present internal states of the voltage and current at each node.

Further, on the right side in Equation 6, (V₁ . . . V_{N}, I₁ . . . I_{N}) having a modified symbol “˜” over the character present the measured values (including not only actual measured values but also estimated values). However, in the description, the characters are shown without the modified symbol “dot” or “˜” for the convenience of the presentations.

Further, M_{V}, M_{I} in Equation 6 are matrices which describe the presence or absence of the measured values of the state amount on the voltage and current as described above, respectively, and M_{V} (voltage) has elements shown in the following Equation 7.

$$\begin{matrix}[ Equation 7 ] & \\ {M}_{V} = [ \begin{matrix}0 & 1 & 0 & 0 & 0 & 0 & … & 0 \\ 0 & 0 & 1 & 0 & 0 & 0 & … & 0 \\ 0 & 0 & 0 & 0 & 1 & 0 & … & 0\end{matrix} ] & Equation 7\end{matrix}$$

In the example shown in Equation 7, elements of “1” in columns 2, 3, 5 indicate that the voltage has been measured by the sensor 102 (FIG. 1) at the nodes 2,3, 5, and associate the state amount Vₚ (with a “dot”) with the measured value of the state amount Vₚ (with “˜”)

Further, M_{I} (current) associates the state amount Iₚ (with a “dot”) with the measured value of the state amount Iₚ (with “˜”) to be presented in the same manner. However, in a case where the measurement points for the voltage are different from those for the current, the composition of 1, 0 in the determinant will be different.

Equation 6 is a fundamental equation for state estimation and will be presented hereinbelow in a simplified form as the following equation.

### <<Presentation of Simplified Equation>>

[Equation 8]

Sy=b Equation 8

In Equation 8, S on the left side is a coefficient matrix composed of A, M_{V}, M_{I} shown on the left side in Equation 6, and y is a variable vector constituted by the state amounts Vₚ, Iₚ (1≦p≦N) shown on the left side in the equation 6.

Further, in Equation 8, b on the right side corresponds to the entire right side in Equation 6, and is a constant vector composed of 0_{N-1}, M_{V}, M_{I} and the measured values of the state amounts Vₚ, Iₚ (1≦p≦N).

With the mathematical model above, a description will be given of a function of the system division unit 105 (FIG. 1).

### <<General Solution to Underdetermined Problem>>

First, Equation 8 will be solved for the variable vector y. In a case where Equation 8 is an underdetermined problem due to lack of the measured values of the state amounts Vₚ, Iₚ, that is, in a case where the coefficient matrix S has a rank deficiency, Equation 8 is solved by using a pseudo-inverse matrix S⁺ of S.

In short, a general solution of the variable vector y for minimizing an error norm in Equation 8 is given by the following Equation 9, using the pseudo-inverse matrix S⁺ of S.

It is noted that the norm (norm, vector norm) corresponds to a “length” of a vector, or a “distance” in a vector space.

[Equation 9]

y=S⁺b+Nul(S)z Equation 9

The left side of Equation 9 is, as described above, the general solution of a variable vector for minimizing the error norm.

The first terra on the right side in Equation 9 presents a particular solution y₀ which minimizes the solution norm, of the general solution y in a row space of the coefficient matrix S.

In addition, the second term on the right side presents a redundant solution w in a null space Nul(S) of the coefficient matrix S. In Equation 9, “z” is an arbitrary vector. It is noted that, in accordance with a customary practice, the null space is presented with Nul.

<<Presentation of Equation Separated into Observable Subsystem and Unobservable Subsystem>>

Here, focusing on the null space Nul(S), assuming that i-th elements of the base are all 0s, i-th elements of the corresponding redundant solution w are always 0s, resulting in that the general solution y does not have redundancy with respect to the i-th elements.

Based on this reference, the elements of the general solution y are rearranged to Y_{U} without redundancy and Y_{R} with redundancy, and elements of S⁺ Nul(S) are rearranged accordingly, so that. Equation 9 is rewritten as shown in the following Equation 10.

$$\begin{matrix}[ Equation 10 ] & \\ [ \begin{matrix}{y}_{U} \\ {y}_{R}\end{matrix} ] = [ \begin{matrix}{P}_{U} \\ {P}_{R}\end{matrix} ] b + [ \begin{matrix}{K}_{U} \\ {K}_{R}\end{matrix} ] z & Equation 10\end{matrix}$$

On the left side in Equation 10, a node for which Y_{U} includes the state amount is observable and a node for which y_{R} includes the state amount is unobservable. Thus, the system division unit 105 (FIG. 1) divides the unobservable power system in which the measured values of the state amounts lacks with respect to the state amounts into the observable subsystem, and the unobservable subsystem.

It is noted that one of the voltage and current at the same node may not have redundancy while the other may have it. The observable subsystem and unobservable subsystem obtained in this case may have the voltage and current separately.

The above process is performed by the system division unit 105 (FIG. 1), for dividing the power system into the observable subsystem where the state amount defined based on the above measured values of the state amount does not have redundancy and the unobservable subsystem where the state amount defined based on the measured values of the state amount has redundancy.

Further, when dividing the power system into the observable subsystem and unobservable subsystem, the system division unit 105 performs it based on redundancy of the solution of the state amount obtained by solving simultaneous equations regarding the state amount, the system information and the measured values of the state amount with the calculation unit 110 (FIG. 1).

### <<Presentation of Equations Separated for Observable Subsystem and Unobservable Subsystem>>

Next, a description will be given of a function of the state estimation unit 106 (FIG. 1). The upper row of Equation is an equation for the state estimation on the observable subsystem, and the following Equation 11 is obtained from the upper row of Equation 10.

[Equation 11]

y_{U}=P_{U}b+K_{U}z Equation 11

Solving Equation 11 gives the estimated value of the state amount.

Since K_{U} on the right side in Equation 11 is a zero matrix (term having no redundancy), the estimated value of the state amount in the observable subsystem is uniquely determined as a particular solution y_{U0} based on P_{U} derived from the pseudo-inverse matrix S⁺ and b.

In the observable subsystem, the solution y_{U0} is the estimated value of the state amount which minimizes the error norm derived from Equation 8, that is, which satisfies the power equation and the measured value of the state amount with the least square error.

The above calculation for calculating the estimated value of the state amount in the observable subsystem is executed by the state estimation unit 106 (FIG. 1) with the calculation unit 110 (FIG. 1).

Further, solving the equation 11 to set the solution as an estimated value of a state amount is equivalent to “the state estimation unit sets the solution of the state amount obtained by solving the simultaneous equations on the state amount, the system information and the measured value of the state amount in the observable subsystem by the calculation unit as the estimated value of the state amount”.

### <<State Estimation Equation on Unobservable Subsystem>>

Next, a description will be given of a function of the state range estimation unit 107 (FIG. 1). The lower row in above Equation is an equation for the state estimation on the unobservable subsystem, and the following equation 12 is obtained from the lower row in the above equation 10.

[Equation 12]

y_{R}=P_{R}b+K_{R}z Equation 12

Solving Equation 12 gives the estimated value of the state amount.

The first term on the right side in Equation 12 is a particular solution y_{R0} and is uniquely determined based on P_{R} derived from the pseudo-inverse matrix S⁺ and b.

While, the second term on the right side derived from the null space Nul (S) is a redundant solution W_{R}. Since K_{U} is a zero matrix to the base of the Nul (S) which is linearly independent, each column of K_{R} is also a linearly independent base. The redundant solution W_{R} takes an arbitrary value on a span (K_{R}). It is noted that the span (K_{R}) indicates a subspace which spans from the linearly independent base of K_{R} and is presented according to a usual presentation.

Here, a value range of the state amount is limited by adding a unique constraint condition to the power system in Equation 12. In other words, the estimated range of the state amount is calculated.

The above calculation for calculating estimated range of the state amount in the unobservable subsystem above is executed by the state range estimation unit 107 (FIG. 1) with the calculation unit 110 (FIG. 1).

Further, the above-mentioned “solving Equation 12 and adding the unique constraint condition to the power system in Equation 12 to limit the value range of the state amount for calculating the estimated range of the state amount” can also be described as follows. That is, the description above is equivalent to a description of “the state range estimation unit sets the value range of the particular solution of the state amount and the general solution which is a sum of the redundant solution as an estimated range of the state amount, the particular solution and the general solution being obtained by solving the simultaneous equations regarding the state amount, the system information and the measured value of the state amount in the unobservable subsystem with the calculation unit”.

By calculating the estimated range of the state amount for the state amount in the unobservable subsystem as described above, the estimation for the state amount in the unobservable subsystem where sensors are insufficient in number to the system state amount can be obtained.

Various methods can be conceivable for limiting the value range of the state amount to calculate the estimated range of the state amount, and three of them are shown below.

### <<First Method for Limiting Value Range of Redundant Solution>>

A first method for limiting a value range of a redundant solution is to calculate, based on the nature of a row space being orthogonal to a null space in a coefficient matrix S, a value range of a redundant solution.

The orthogonality is established for the particular solution Y₀ and the redundant solution w in Equation 9. Further, since the redundant solution w_{R} in Equation 12 is a vector in which elements to be always 0 are removed from the redundant solution w in Equation 9 and rearranged, the orthogonality is also established for the particular solution Y_{R0} and the redundant solution W.

Therefore, the following Equation 13 is established for solution norms of the general solution y_{R}, the particular solution y_{R0} and the redundant solution w_{R} in Equation 12.

[Equation 13]

∥y_{R}∥²=∥y_{R0}∥²+∥w_{R}∥² Equation 13

Here, since the particular solution y_{R0} is unique, the solution norm can also be uniquely calculated. Further, assuming that each state amount cannot take a value greater than the constraint value set in the constraint condition database 109 for the general solution y_{R}, the solution norm at that time is the maximum value ∥w_{R}∥ₘₐₓ.

The constraint value of the state amount is a rated current, for example, for the currents in the load node and the SVC node, and may be a threshold voltage of an overvoltage protection relay arranged in the system for the voltage. Thus, by setting the maximum value ∥w_{R}∥ₘₐₓ of the solution norm of the general solution y_{R}, the range of the solution norm ∥w_{R}∥ of the redundant solution w_{R} is defined by the following Equation 14.

[Equation 14]

∥w_{R}∥²−∥y_{R}∥²−∥y_{R0}∥²≦∥y_{R}∥ₘₐₓ²−∥y_{R0}∥²=∥w_{R}∥ₘₐₓ² Equation 14

<<Calculation of Maximum Value of each Element in Redundant Solution>>

Next, the maximum value of each element in the redundant solution w_{R} is calculated from the maximum value ∥w_{R}∥ₘₐₓ of the solution norm of the redundant solution w_{R}.

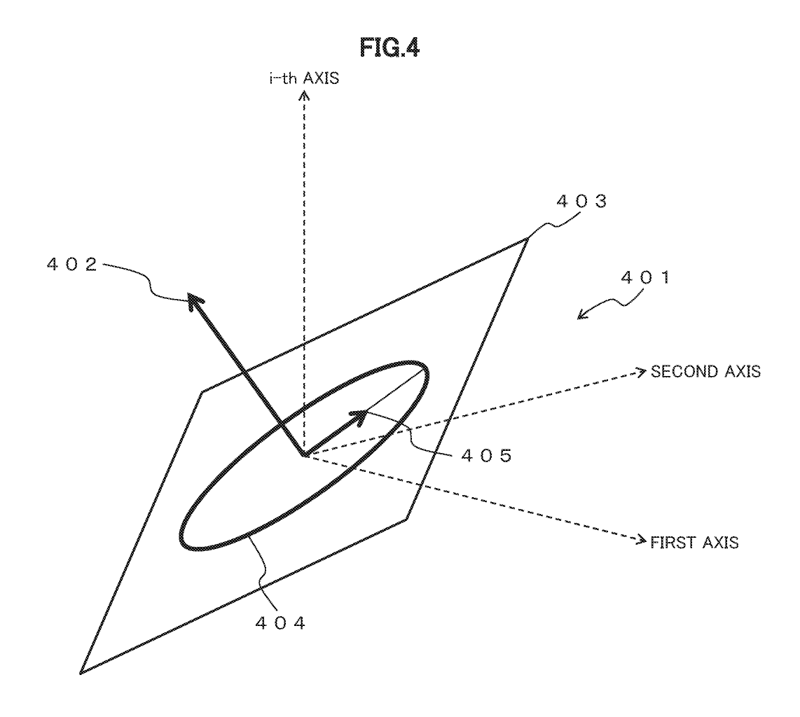

FIG. 4 is a schematic diagram showing a method for calculating the maximum value of each element of the redundant solution w_{R} from the maximum value ∥w_{R}∥ₘₐₓ of the solution norm of the redundant solution w_{R}.

In FIG. 4, a reference numeral 401 indicates a state space having state amounts of respective elements in a general solution y_{R} as axes. The state space includes a first axis, a second axis, . . . , and an i-th axis.

A reference numeral 402 indicates a vector (particular solution vector) of a particular solution y_{R0}=P_{R}b.

A reference numeral 403 indicates a subspace span (K_{R}) where the redundant solution w_{R} is present.

A synthetic vector of the particular solution vector 402 and an arbitrary vector on the subspace 403 is a general solution vector.

A reference numeral 404 is a cross section of a hypersphere to be described later.

A reference numeral 405 is a unit vector to be described later.

Here, the fact that the range of the solution norm of the redundant solution w_{R}is limited indicates that, in the subspace 403, the vector of the redundant solution w_{R} is present inside the hypersphere 404 having the maximum value ∥w_{R}∥ₘₐₓ as a radius. It is noted that the reason for calling the hypersphere 404 as a “hypersphere” is that the hypersphere is a spherical surface defined by the first axis, the second axis, . . . , and the i-th axis.

In this case, when the length of the unit vector 405 of which gradient in the i-th axis direction is the maximum on the subspace 403 is multiplied by ∥w_{R}∥ₘₐₓ, the i-th element in the redundant solution w_{R} takes the maximum value. Such a unit vector f₁ is calculated by the following Equation 15.

[Equation 15]

fᵢ=pᵢ/∥pᵢ∥, pᵢ=K_{R}(K_{R}^{T}K_{R})⁻¹K_{R}^{T}eᵢ Equation 15

In Equation 15, eᵢ is a unit vector having the i-th element of 1, and pᵢ is a projection of the eᵢ to the span (K_{R}).

The i-th element of a vector ∥w_{R}∥ₘₐₓfᵢ formed by the unit vector fᵢ multiplied by ∥w_{R}∥ₘₐₓ is the maximum value w_{Rmaxi} on the i-th element in the redundant solution w_{R}.

Further, the value range of the i-th element in the redundant solution w_{R} is [−w_{Rmaxi}, w_{Rmaxi}]. The value range of the i-th element y_{Ri} in the general solution y_{R} for the value range of the redundant solution w_{R} and the i-th element y_{R0i} in the particular solution is given by the following Equation 16.

[Equation 16]

y_{R i}∈[y_{R0 i}−w_{Rmaxi}, y_{R0 i}+w_{Rmaxi}] Equation 16

<<(Case of Value Range of General Solution being out of Constraint Value>>

In a case where the value range of the general solution y_{R} is out of the constraint value, the value range is rounded off to the constraint value. By calculating each element by Equation 16, the error norm derived from Equation 8 is minimized for the unobservable subsystem. That is, the estimated range of the state amount can be obtained which satisfies the power equation and the measured value of the state amount with the least square error.

A first method to limit the value range of the redundant solution as described above is a method in which “the state range estimation unit limits the value range of the redundant solution of the state amount based on the constraint value of the state amount”.

Further, the first method is also referred to as a method in which “the state range estimation unit sets a sum of the particular solution vector of the state amount and the redundant solution vector obtained by solving the simultaneous equations with the calculation unit as the general solution vector, and subtracts the vector norm of the particular solution vector from the maximum value of the vector norm of the general solution vector defined by the constraint value, to calculate the maximum value of the vector norm of the redundant solution vector for limiting the value range of the redundant solution vector”.

Further, the first method for limiting the value range of the redundant solution has a feature in which the accuracy to limit the value range is low, but the calculation amount is small, as compared with a second and a third methods to be described later.

### <<Second Method for Limiting Value Range of Redundant Solution>>

A second method for limiting the value range of the redundant solution is to calculate the value range of the redundant solution w having the constraint value of each state amount defined in the constraint, condition database 109 (FIG. 1) as a boundary condition.

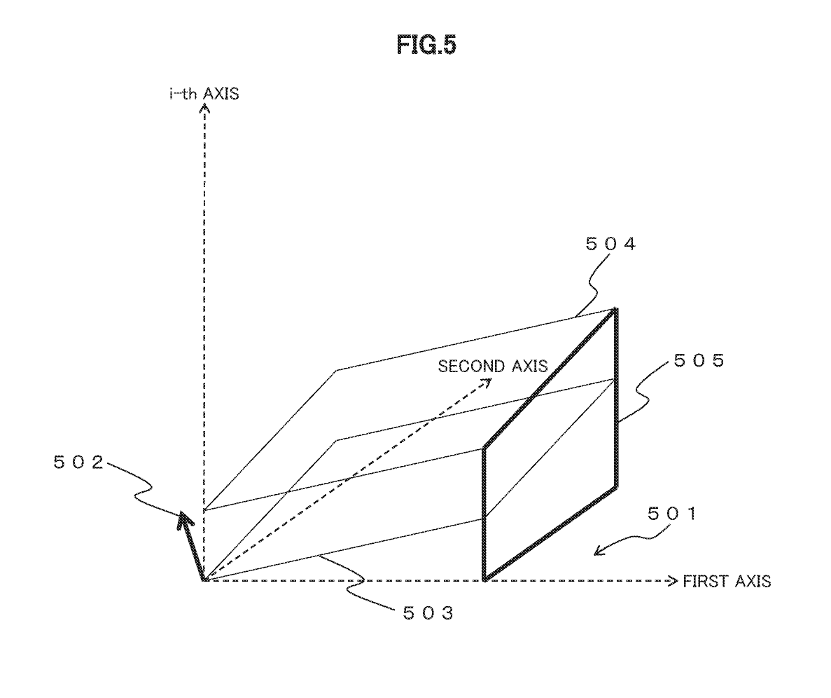

FIG. 5 is a schematic diagram showing a calculating method for the value range of the redundant solution.

In FIG. 5, a reference numeral 501 indicates a state space having the state amounts of respective elements in the general solution y_{R} as axes. The state space includes a first axis, a second axis, . . . , an i-th axis.

A reference numeral 502 indicates a vector (particular solution vector) of the particular solution y_{R0}=P_{R}b.

A reference numeral 503 indicates a subspace span (K_{R}) where the redundant solution w_{R} is present.

A synthetic vector of the particular solution vector 502 and an arbitrary vector on the subspace 503 is the general solution vector which forms a subset. 504.

A hyperplane 505 indicates the constraint values of the state amount which are present on the first: axis, the second axis, . . . , and the i-th axis, respectively, and is a (hyper) plane defined by the constraint values.

Defining the value range of the redundant solution w_{R} having the constraint values of the state amount as boundary conditions indicates that the subset 504 is cut off by the hyperplane 505.

The value range of the redundant solution w_{R} is calculated by solving simultaneous inequalities of the following Equations 17A and 17B for w_{Ri}. It is noted that W_{R} is a vector and W_{Ri} is an element contained therein.

[Equations 17A and 17B]

w_{R}=K_{R}z Equation 17A

y_{Rlim1i}≦y_{R0 i}+wᵣᵢ≦y_{Rlim2i} Equation 17B

In Equation 17B, y_{Rlim1i}, y_{Rlim2i} are upper and lower limit values of the state amount defined in the constraint condition database 109. Since there are so many solutions for such simultaneous inequalities, a description thereof will be omitted in the present embodiment.

The second method for limiting the value range of the redundant solution as described above is a method in which “the state range estimation unit limits the value range of the redundant solution of the state amount based on the constraint. values of the state amount”.

Further, the second method is also referred to as a method in which “the state range estimation unit sets a sum of the particular solution vector of the state amount: and the redundant: solution vector obtained by solving the simultaneous equations with the calculation unit as the general solution vector, and subtracts the particular solution vector from the sum by setting the constraint values as boundary conditions of the general solution vector to limit the value range of the redundant solution vector.”

Still further, the second method for limiting the value range of the redundant solution has a feature in which the calculation amount is large and implementation is complex, but an accurate solution of the value range can be obtained_{—}

### <<Third Method for Limiting Value Range of Redundant Solution>>

A third method for limiting the value range of the redundant solution uses a nature that a particular solution obtained by the pseudo-inverse matrix is the minimum solution of the solution norm in Equation 9. Then, the value range of the voltage in the state amount is limited based on the rated value of the current defined in the constraint condition database 109 (FIG. 1)

Firstly, a variable vector y is applied with weighting based on a type (voltage, current) of the state amount and Equation 8 is rewritten as the following Equation 18.

[Equation 18]

SH⁻¹(Hy)=b Equation 18

A weight matrix H shown on the left side in Equation 18 is a diagonal matrix having a weighting coefficient associated with each element of the variable vector as a diagonal component, and is described as follows by using “diag” indicating a diagonal matrix.

H=diag ([h_V1, h_V2, . . . , h_VN, h_I1, h_I2, . . . , h_IN])

It is noted that h_Vp is a weighting coefficient corresponding to the voltage state amount of the node p, and h_Ip is a weighting coefficient corresponding to the current state amount Iₚ of the node P where 1≦p≦N.

By solving Equation 18 for Hy, a particular solution Hy_{H0} can be newly obtained which minimize a solution norm for Hy. The particular solution Hy_{H0} is obtained by the following Equation 19, by using pseudo-inverse matrix (SH⁻¹)⁺.

[Equation 19]

Hy_{H0}=(SH⁻¹)⁺b Equation 19

Further, Equation 19 is solved for y_{H0} to obtain the following Equation 20.

[Equation 20]

y_{H0}=H⁻¹(SH⁻¹)⁺b Equation 20

Since Equation 18 and Equation 8 are equivalent, the nature that the solution y_{H0} is a solution to minimize the error norms on both sides in Equation 8 is equivalent. On the other hand, the solution y_{H0} in the equation 20 represents one of the general solutions of Equation 9, and the difference between the solution y_{H0} in Equation 20 and the particular solution y₀ in Equation 9 represents the redundant solution w in Equation 9.

### <<Method for Calculating Estimated Voltage Range>>

Next, a method for calculating the estimated voltage range (lower limit voltage and upper limit voltage) will be described by using the weighted solution y_{H0} in Equation 20. The method mainly includes three steps. The steps will be described below.

### [Step 1]

As a step 1, the weighting coefficient h_Ip associated with the current state amount among the diagonal components constituting the weight matrix H is set to a larger value than the weighting coefficient h_Vp associated with the voltage state amount.

### [Step 2]

As a step 2, Equation 20 is solved to obtain a solution in which a sum of squares of the current state amounts Iₚ an respective nodes is small and a sum of squares of the voltage state amounts Vₚ in respective nodes is large. If the weighting coefficient h_Ip is set to be sufficiently large in the step 1, this is the solution to minimize the sum of squares of the current state amount among solutions which satisfy the power equation and a measurement equation with the minimum error norm.

### [Step 3]

As a step 3, an absolute value of the current state amount at this time is evaluated, and if any of the state amounts does not exceed the rated current, h_Ip which has been set in the step 1 is reset to a relatively smaller value (for example, to a value having 95% of the original coefficient) , to reduce the weighting for the current.

Here, returning to the step 2 to solve Equation 20, a solution can be obtained, in which the sum of squares of the current state amount relatively turns to be large.

By repeating the above steps, the sum of squares of the current state amount turns to be gradually larger and the sum of squares of the voltage state amount turns to be gradually smaller in the solution y_{H0}.

In short, in the step 3, when an absolute value of any of the current state amounts exceeds the rated current, the solution at that time is, in a range to satisfy Equation 8 and the rated current defined in the constraint condition database 109, the minimum solution of the voltage norm which minimizes the sum of squares of the voltage state amount.

In this case, if the reference of the voltage state amount is set, for example, at 0 volt, the minimum solution of the voltage norm represents a solution which gives the lower limit voltage. On the other hand, if the reference of the voltage state amount is set to a value sufficiently larger than a specified voltage, the minimum solution of the voltage norm represents the solution which gives the upper limit voltage. It is noted, as an example of being set to the sufficiently large value described above, the voltage state amount may be indicated by a difference from 10000 volts in a system having the specified voltage of 6600 volts.

Further, in a process of execution of steps 2 and 3 repetitively, since the weighting coefficient h_p is discretely reduced, the minimum solution of the voltage norm obtained in the process is not an accurate solution but an approximate solution.

Then, until the absolute value of the current state amount exceeds the rated current, the weighting coefficient h_Ip is adjusted so that the absolute value of the current state amount converges to the rated current, instead of simply reducing the weighting coefficient h_Ip. The adjustment allows the approximate accuracy of the minimum solution of the voltage norm to be more accurate.

Further, if the rated current is different depending on the node, weighting is made such that a product of the associated weighting coefficient h_Ip and the rated current is set to have the same value for each node. With this weighting, the solution obtained in the step 2 turns to be a current state amount which is normalized to the rated current. Alternatively, the same solution can be obtained by writing Equation 8 with the current state amount which is normalized, by the rated current in advance and solving Equation 18.

### <<Flow of Calculating Step in Third Method>>

The calculation step in the third method described above will be shown by a flowchart below.

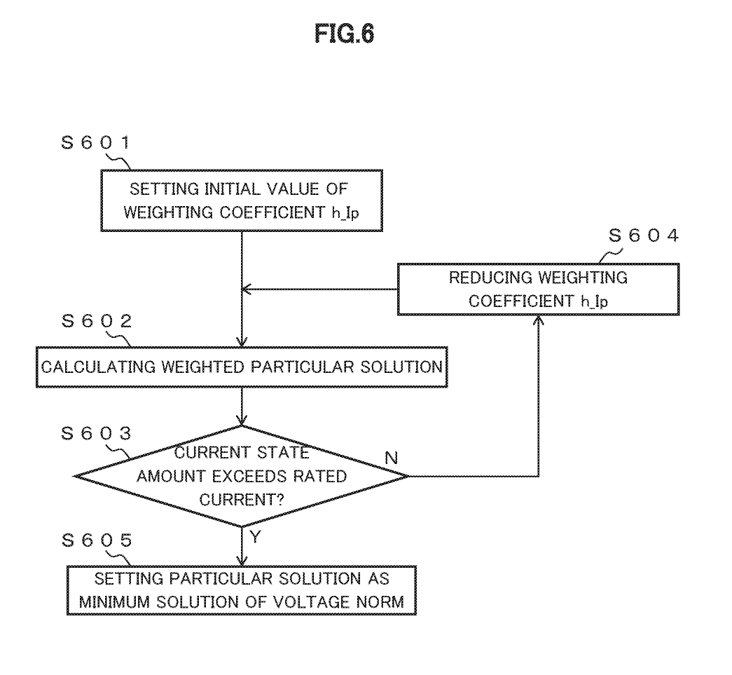

FIG. 6 is a flowchart showing the calculation step in the third method for limiting the value range of a redundant solution according to the embodiment of the present invention.

In FIG. 6, step S601 is the step 1 described above, in which the weighting coefficient h_Ip is set to the sufficiently large coefficient as an initial value. Then, step S602 is executed.

Step S602 is the step 2 described above, and the weighted particular solution is calculated so that the sum of squares of the current state amount decreases, to obtain the solution. Then, step S603 is executed.

Step S603 is the step 3 described above, and determines if the absolute value of the current state amount exceeds the rated current. If the current state amount at any node does not exceed the rated current (N), step S604 is executed. Alternatively, if the current state amount at any node exceeds the rated current (Y), step S605 is executed.

In step S605, the solution at that time (particular solution weighted so that the sum of squares of the current state amount decreases and the current state amount at some node exceeds the rated current) is set to be the minimum solution of the voltage norm.

It is noted that, in step S604 branched from step S603 above, the weighting coefficient h_Ip is decreased to reduce the weighting on the current, and step S602 is executed again.

The third method for limiting the value range of the redundant solution as described above is equivalent to a method in which “the state range estimation unit uses the calculation unit to weight the state amount and solve the simultaneous equations for obtaining a new solution representing one of the general solutions, and sets a voltage component of the solution at a stage where a current component of the solution reaches the rated current defined by the constraint value as the estimated range of the state amount, while weighting for the current component in the state amount is gradually reduced”.

Further, the third method for limiting the value range of the redundant solution has a feature in which the calculation amount is large, but implementation is simple and an approximate solution of the value range can be obtained.

The three methods for calculating the estimated range of the state amount using the state range estimation unit 107 (FIG. 1) are described above, but the calculation method for the estimated range of the state amount using the constraint, value defined in the constraint condition database 109 (FIG. 1) is not limited thereto.

### <<Function of Display Device 111>>

Next, a function of the display device 111 (FIG. 1) will be described.

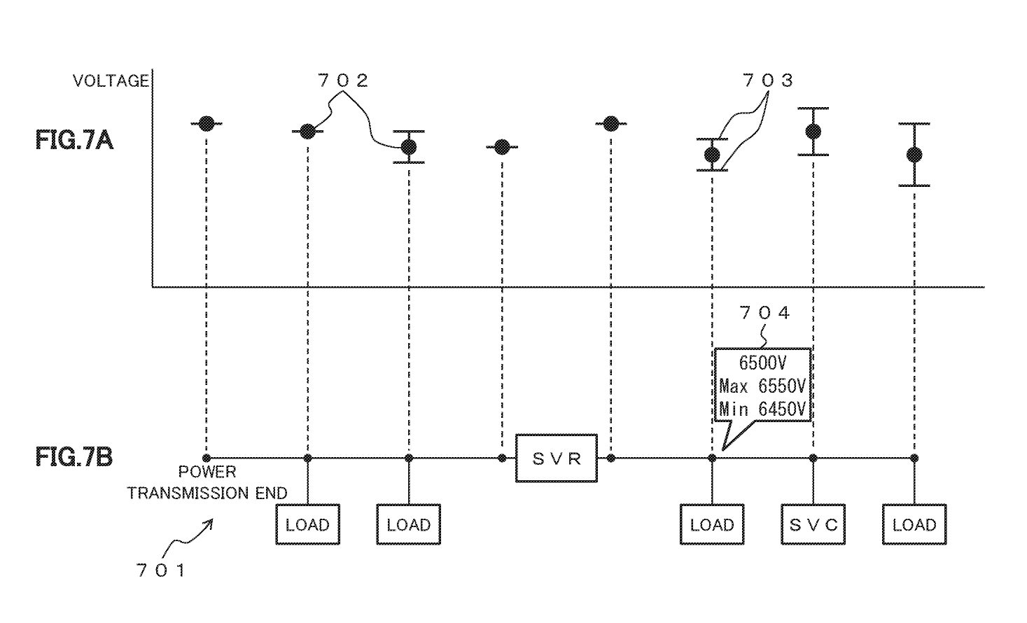

FIGS. 7A and 7B are diagrams showing an example of a screen display on the display device 111, in which FIG. 7A indicates representative values of the state amounts 702 and ranges of the state amounts 703 at respective modes, and FIG. 7B indicates a system diagram 701 of the power system.

In FIG. 7B, the system diagram 701 of the power system is shown with an example of nodes and branches based on the system information recorded in the system information database 108 (FIG. 1). The nodes in the system diagram 701 are each connected with the load or the SVC (Static Var Compensator). Further, the branch shown at approximately the center is connected with the SVR (Step Voltage Regulator).

In FIG. 7A, the horizontal axis corresponds to an arrangement of respective nodes in the system diagram 701 in FIG. 7B, and the vertical axis indicates the voltage.

In FIG. 7A, the representative values of the state amounts 702 are displayed on a graph, in which the unique solution y_{U}=y_{U0} calculated by the state estimation unit 106 (FIG. 1) for the observable subsystem and the particular solution y_{R0} calculated by the state range estimation unit 107 (FIG. 1) for the unobservable subsystem are associated with the nodes in the system diagram 701.

Further, ranges of the state amount 703 are displayed on the graph, in which the value ranges of the general solution y_{R} calculated by the state range estimation unit 107 for the unobservable subsystem are associated with the nodes in the system diagram.

It is noted that the numerals 702 for the black circles indicate the representative values of the respective state amounts. Further, the numerals 703 for the two lines indicate the ranges of the respective state amounts.

Still further, since the solution y_{U} (=y_{U0}) in the observable subsystem is unique, the width of the range of the state amount 703 for the observable subsystem is zero.

Since the general solution y_{R} in the unobservable subsystem has the value range of the redundant solution, the width (between the upper and lower limits) of the range of the state amount 703 has a given value.

Yet further, a numerical frame 704 describes the same information as the representative value of the state amount. 702 and the range of the state amount 703 with numeric values on the system diagram 701.

### <<Function of Recording Device 112>>

Next, a function of the recording device 112 will be described.

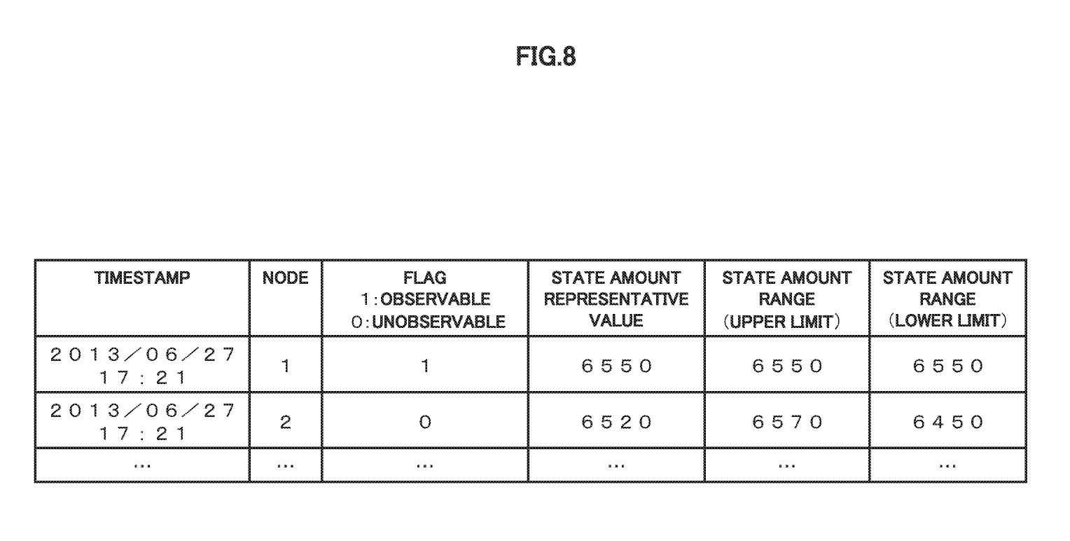

FIG. 8 is a table showing an example of a system log outputted from the recording device 112.

In FIG. 8, the system log exemplifies items of a timestamp, a node, a flag, a representative value of the state amount, a range (upper limit) of the state amount, and a range (lower limit) of the state amount.

The system log added with a timestamp showing a recorded date and time is outputted everytime the power system state estimation device 100 (FIG. 1) is executed.

Further, the system log records the same information as the flag indicating which of the observable/unobservable subsystem the node belongs to, the representative value of the state amount 702 (FIG. 7) and the range of the state amount 703 (FIG. 7) with numerical values to be outputted.

Further, the items in the system log are not limited to the above. Depending on the calculation method, the maximum value ∥w_{R}∥ₘₐₓ of the solution norm of the redundant solution in Equation 14, for example, is outputted.

### <<Process Flow of Power System State Estimation Device>>

Next, a description will be given of a process flow of the power system state estimation device according to the embodiment.

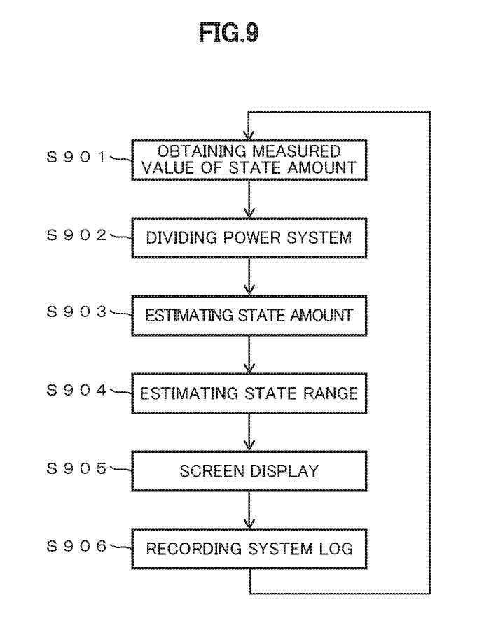

FIG. 9 is a flowchart showing an exemplary process flow of the power system state estimation device according to the embodiment of the present invention.

In FIG. 9, step S901 is for obtaining a measured value of the state amount. In short, the measured value of the state amount obtained via the communication line 103 (FIG. 1) is recorded in the measured value database 104 (FIG. 1) in step S901.

Step S902 is for dividing the power system by the system.

division unit 105 (FIG. 1). In step S902, the system division unit 105 is inputted with the system information and the measured value of the state amount to divide the power system into the observable subsystem and the unobservable subsystem (system division step).

Step S903 is for estimating the state amount by the state estimation unit 106 (FIG. 1). In step S903, the state estimation unit 106 is inputted with the system information and the measured value of the state amount to calculate the estimated value of the state amount in the observable subsystem (estimated value of the state amount calculation step).

Step S904 is for estimating the state range by the state range estimation unit 107 (FIG. 1). In step S904, the state range estimation unit 107 is inputted with the system information, the measured value of the state amount and the constraint value of the state amount to calculate the estimated value of the state range in the unobservable subsystem (estimated value of the state range calculation step).

Step S905 is for displaying the information on a screen. In step S905, the state estimated value and the state estimated range are displayed on the display device 111 (FIG. 1).

Step S906 is for recording the system log. In step S906, the system log is recorded by the recording device 112 (FIG. 1) Then, step 901 is repeated again.

The power system state estimation device 100 (FIG. 1) executes the processing of each step above at regular intervals or in synchronous with obtaining the measured value of the state amount.

It is noted that, in the third method, the minimum solution of the voltage norm also includes the state amount relating to the observable subsystem, and the value thereof is equal to the estimated value of the state amount obtained by the calculation processing instep S903. Therefore, the calculation processing in step S903 and step S904 can be executed at the same time.

### DESCRIPTION OF REFERENCE NUMERALS

100 power system state estimation device
101 power system
102 sensor (information acquisition device)
103 communication line (information acquisition device)
104 measured value database
105 system division unit
106 state estimation unit
107 state range estimation unit
108 system information database
109 constraint condition database
110 calculation unit
111 display device (peripheral device)
112 recording device (peripheral device)
201 power transmission end
202, 206, 207, 209 load end
203 branch end
204, 205 SVR end
208 SVC end
211 power distribution line
212, 216, 217, 219, 319 load
218, 318 SVC
234, 237 power distribution system
245, 345 SVR
401, 501 state space
402, 502 particular solution vector
403, 503 subspace
404 hypersphere
405 unit vector
504 subset
505 hyperplane
701 system diagram
702 representative value of state amount
702 range of state amount
704 numerical frame

1. A power system state estimation device, for estimating a state amount of a power system, comprising:
a calculation unit that executes calculations on the power system;
a system division unit that is inputted with system information and a measured value of the state amount of the power system to divide the power system into an observable subsystem. and an unobservable subsystem with reference to a calculation result of the calculation unit;
a state estimation unit that is inputted with the system information and the measured value of the state amount to calculate an estimated value of the state amount in the observable subsystem divided by the system division unit with reference to the calculation result of the calculation unit; and
a state range estimation unit that is inputted with the system information, the measured value of the state amount and a constraint value of the state amount of the power system and calculates an estimated range of the state amount in the unobservable subsystem divided by the system division unit.

2. The power system state estimation device according to claim 1, further comprising a display device that displays the estimated value of the state amount calculated by the state estimation unit and the estimated range of the state amount calculated by the state range estimation unit on a system diagram illustrated with the system information.

3. The power system state estimation device according to claim 1, further comprising a recording device that outputs the estimated value of the state amount calculated by the state estimation unit and the estimated range of the state amount calculated by the state range estimation unit on a recording medium.

4. The power system state estimation device according to claim 1, wherein the system division unit divides the power system into the observable subsystem in which the state amount defined based on the measured value of the state amount does not have redundancy and the unobservable subsystem in which the state amount defined based on the measured value of the state amount has redundancy.

5. The power system state estimation device according to claim 4, wherein the system division unit divides the power system into the observable subsystem and the observable subsystem based on the redundancy of a solution of the state amount obtained by solving simultaneous equations regarding the state amount, the system information and the measured value of the state amount with the calculation unit.

6. The power system state estimation device according to claim 1, wherein the state estimation unit sets a solution of the state amount obtained by solving a simultaneous equations regarding the state amount, the system information and the measured value of the state amount in the observable subsystem with the calculation unit as the estimated value of the state amount.

7. The power system state estimation device according to claim I, wherein the state range estimation unit sets a value range of a particular solution of the state amount and a general solution which is a sum of redundant solution as an estimated range of a state amount, the particular solution and the general solution being obtained by solving simultaneous equations regarding the state amount, the system information and the measured value of the state amount in the unobservable subsystem with the calculation unit.

8. The power system state estimation device according to claim 7, wherein the state range estimation unit limits the value range of the redundancy solution of the state amount based on the constraint value of the state amount.

9. The power system state estimation device according to claim 8, wherein the state range estimation unit sets a sum of a particular solution vector of the state amount and a redundant solution vector obtained by solving the simultaneous equations with the calculation unit as a general solution vector, and subtracts a vector norm of the particular solution vector from the maximum value of the vector norm of the general solution vector defined by the constraint value of the state amount, to calculate the maximum value of the vector norm of the redundant solution vector for limiting the value range of the redundant solution vector.

10. The power system state estimation device according to claim 8, wherein the state range estimation unit sets a sum of a particular solution vector of the state amount and a redundant solution vector obtained by solving the simultaneous equations with the calculation unit as a general solution vector, and subtracts the particular solution vector from the sum by setting the constraint value of the state amount as a boundary condition of the general solution vector to limit the value range of the redundant solution vector.

11. The power system state estimation device according to claim 7, wherein the state range estimation unit uses the calculation unit to weight the state amount and to solve the simultaneous equations for obtaining a new solution representing one of the general solutions, and sets a voltage component of the solution at a stage where a current component of the solution reaches the rated current defined by the constraint value as the estimated range of the state amount, while weighting for the current component in the state amount is gradually reduced.

12. A power system state estimation method for use in a power system state estimation device inclusive of a system division unit, a state estimation unit and a state range estimation unit, the method comprising:
dividing, by the system division unit, the power system into an observable subsystem and an unobservable subsystem with reference to a calculation result of a calculation unit, which executes calculations on the power system, by inputting system information and a measured value of a state amount of the power system.;
calculating, by the state estimation unit, an estimated value of the state amount in the observable subsystem divided by the system division unit with reference to the calculation result by the calculation unit, by inputting the system information and the measured value of the state amount; and
calculating, by the state range estimation unit, an estimated value of a state range in the unobservable subsystem divided by the system division unit with reference to the calculation result by the calculation unit, by inputting the system information, the measured value of the state amount and a constraint value of the state amount of the power system.
